(19) United States
(12) Patent Application Publication
(10) Pub. No.: US 2026/0040412 A1
(43) Pub. Date: Feb. 5, 2026

(54) TEMPERATURE CONTROL DEVICE

(71) Applicant: EBNER Industrieofenbau GmbH, Leonding (AT)

(72) Inventors: Robert EBNER, Leonding (AT); Andreas SAUSCHLAGER, Leonding (AT)

(73) Assignee: EBNER Industrieofenbau GmbH, Leonding (AT)

(21) Appl. No.: 18/867,106

(22) PCT Filed: May 19, 2023
(86) PCT No.: PCT/AT2023/060161

§ 371 Date: Nov. 19, 2024

(30) Foreign Application Priority Data
May 20, 2022 (AT) A50357/2022

(51) Int. Cl. H05B 3/64; C30B 11/00; F27B 14/06

(52) U.S. Cl. CPC H05B 3/64; F27B 14/06; C30B 11/003; C30B 11/006; H05B 2203/002; H05B 2203/016

(57) ABSTRACT

A temperature control device includes a first temperature control element, which has at least sectionally a spiral-shaped course, and at least one second temperature control element, which also has at least sectionally a spiral-shaped course, the first and second temperature control elements being positioned so as to be at least partially nested within one another.

The invention relates to a temperature control apparatus comprising a first temperature control element which has at least sectionally spiral-shaped course.

The invention also relates to a temperature control device with a receptacle for a material to be heated and with a temperature control apparatus for heating the material.

It is known that electrical heating apparatus are used to heat a material, in particular to melt the material, for example for the production of single crystals. DE 101 03 691 A1 is one example of many.

The growth of large crystals in particular requires very constant conditions in order to avoid impurities or defects in the crystal lattice as much as possible.

It is the object of the invention to enable the most uniform possible temperature control, in particular heating, of a surface.

The object of the invention is achieved in the temperature control apparatus mentioned at the beginning in that the temperature control apparatus has at least one second temperature control element, which also has at least sectionally spiral-shaped course, the first and second temperature control elements being arranged at least partially nested within one another.

Furthermore, the object of the invention is achieved by the temperature control device mentioned at the beginning, in which the temperature control apparatus is formed according to the invention.

Here, the advantage of the nested arrangement of the temperature control elements is that differences in temperature control with the temperature control elements, which are due to the temperature control elements themselves, can be better compensated for. Temperature control means heating on the one hand, but also cooling on the other. The temperature control apparatus can therefore be a heating apparatus or a cooling apparatus. Accordingly, the term “temperature control” can be understood as “heating”, “warming” or “cooling”. The temperature control apparatus thus enables a more uniform input of energy into a material to be heated or a more uniform output of energy from a material to be cooled. In addition, the length of the individual temperature control elements can be shortened with the same heated or cooled surface compared to a temperature control apparatus with only one spiral-shaped temperature control element, which also allows the energy input into the material to be warmed or heated (these two terms are used synonymously in this description) or cooled to be equalized.

According to one embodiment of the invention, it may be provided that the spiral-shaped courses of the first and second temperature control elements are formed as Fibonacci spirals. With this design, the technical implementation of the nesting of the temperature control elements can be implemented more easily. In addition, the temperature control of a surface is possible with greater homogeneity compared to a differently shaped spiral.

In order to further improve the aforementioned effects, according to further embodiments of the invention it may be provided that the invention has at least a third temperature control element and optionally at least one further temperature control element, which is arranged at least partially nested within the first and the second temperature control element, wherein the spiral-shaped course of the third temperature control element and optionally of the at least one further temperature control element is or are preferably formed as a Fibonacci spirals.

A further improvement in the homogeneity of the temperature control of a surface or the energy input into the material to be heated or the energy removal from the material to be cooled can be achieved according to an embodiment of the invention if the first, the second and the third temperature control element each have a first and a second connection area for electrical contacting and the first connection areas are arranged offset from one another by 120°.

According to another embodiment variant of the invention, it can be provided that all temperature control elements have a common second connection area, which can simplify the design of the temperature control apparatus.

According to a further embodiment variant of the invention, it can be provided that the first and second connection areas form a three-phase connection. As a result, not only is a greater output of the temperature control apparatus achievable, but the power flows can also be improved, so that a more homogeneous heating of a material to be heated can also be achieved.

According to a further embodiment of the invention, it is preferable for the three-phase connection to be formed as a star connection, with the second connection areas of the first, second and third temperature control element forming the star point of the star connection. In particular in conjunction with the design of the temperature control elements as Fibonacci spirals, the surface of the material to be heated can thus be better covered by the temperature control elements. This also makes it easier to arrange the temperature control elements in the temperature control apparatus, as fewer fixing points are required. The same applies if the temperature control elements are electrically operated cooling elements based on the thermoelectric effect, for example. The star point can be used as an earth connection, which means that it can also be used as an attachment point to a housing.

A further improvement in the energy input into the material to be heated can be achieved if, according to an embodiment of the invention, it is provided that the first and second temperature control elements are formed to be at least sectionally flat-wire-shaped.

A corresponding improvement can be achieved if the third temperature control element and the further temperature control element or elements, if present, are also formed to be at least sectionally flat-wire-shaped.

Further homogenization of the energy input into a material to be heated can be achieved if, according to other embodiments of the invention, it is provided that a distance between the first and the second temperature control element is at most 50 mm, and optionally a distance between the first and the third temperature control element and/or between the second and the third temperature control element is at most 50 mm.

To further improve the homogenization of the energy input into a material to be heated, according to one embodiment of the temperature control device it can be provided that the temperature control apparatus, in particular in the design as a heating apparatus, is arranged between at least one reflector element and the receptacle for the material to be heated. With the reflector element, the intermediate areas between the temperature control elements can be better supplied with heating energy. This also improves the energy efficiency of the temperature control device.

In the preferred embodiment variant of the invention, the receptacle for the material to be heated is formed as a crucible for warming or heating the material, in particular for warming or heating material for single crystal growth, since uniform heating of the material is advantageous for these technical areas in particular.

To further improve the energy input into a material to be heated or cooled, a further embodiment of the temperature control device may provide that the first, second and third temperature control elements or generally the temperature control elements of the temperature control apparatus are connected to a load sharing control.

For a better understanding of the invention, it is explained in more detail with reference to the following figures.

They show in a highly simplified, schematic representation:

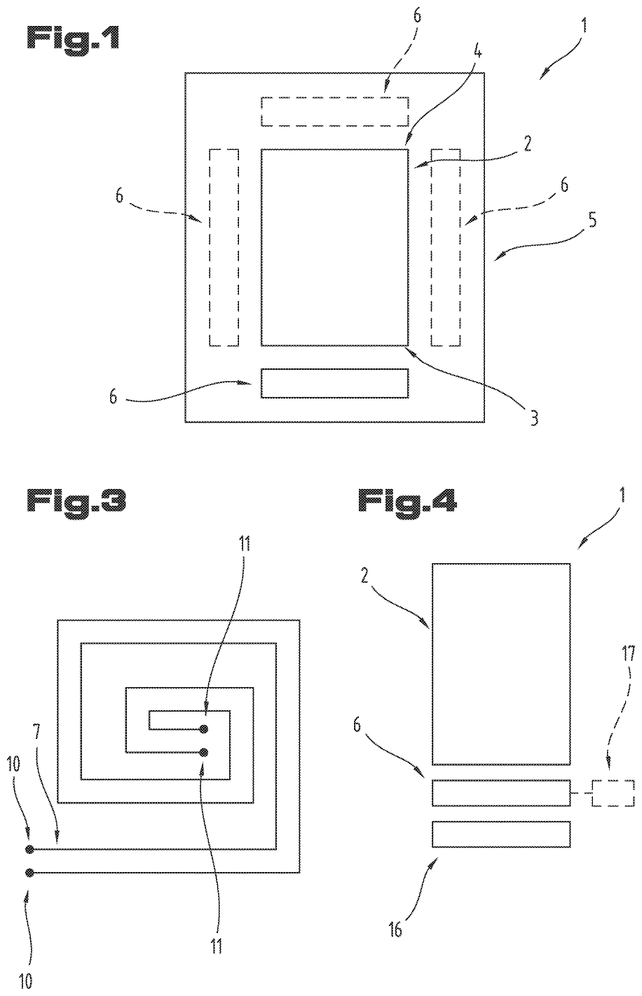

FIG. 1 a temperature control device with at least one temperature control apparatus;

FIG. 2 an embodiment variant of a temperature control apparatus:

FIG. 3 a further embodiment variant of a temperature control apparatus in a plan view:

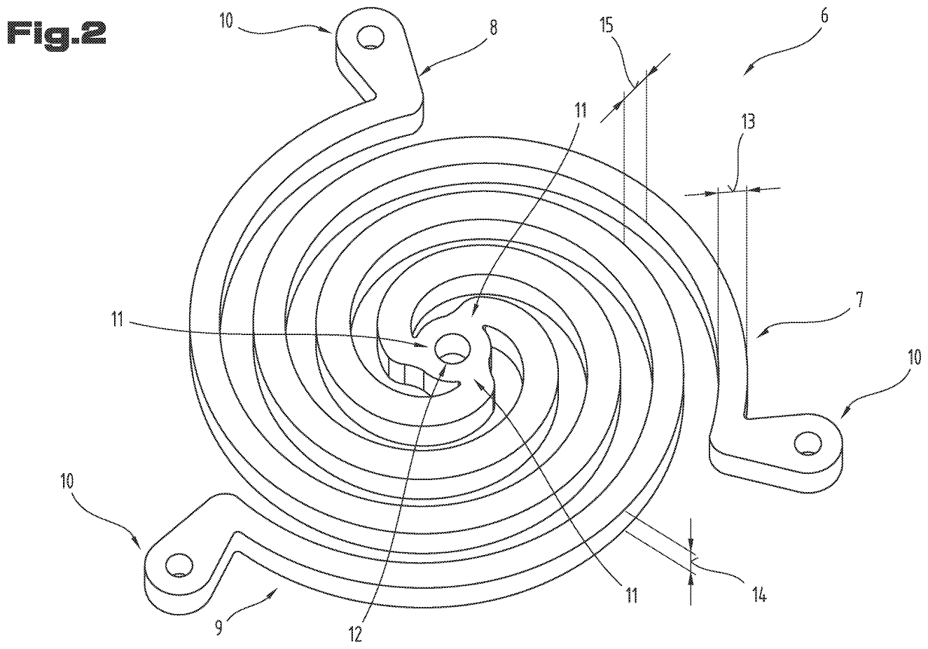

FIG. 4 an embodiment variant of a temperature control device:

FIG. 5 an embodiment variant of a temperature control device:

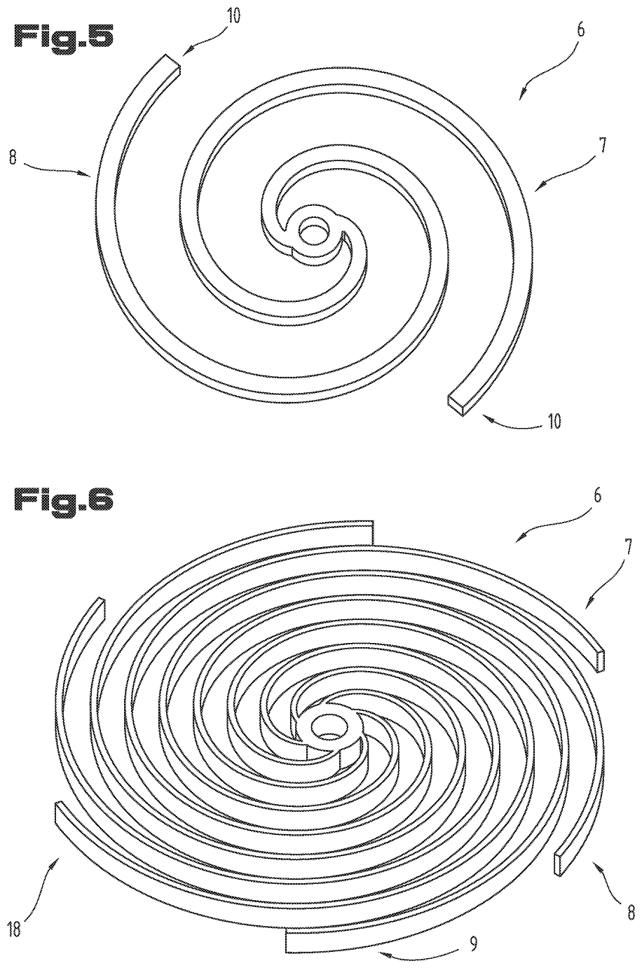

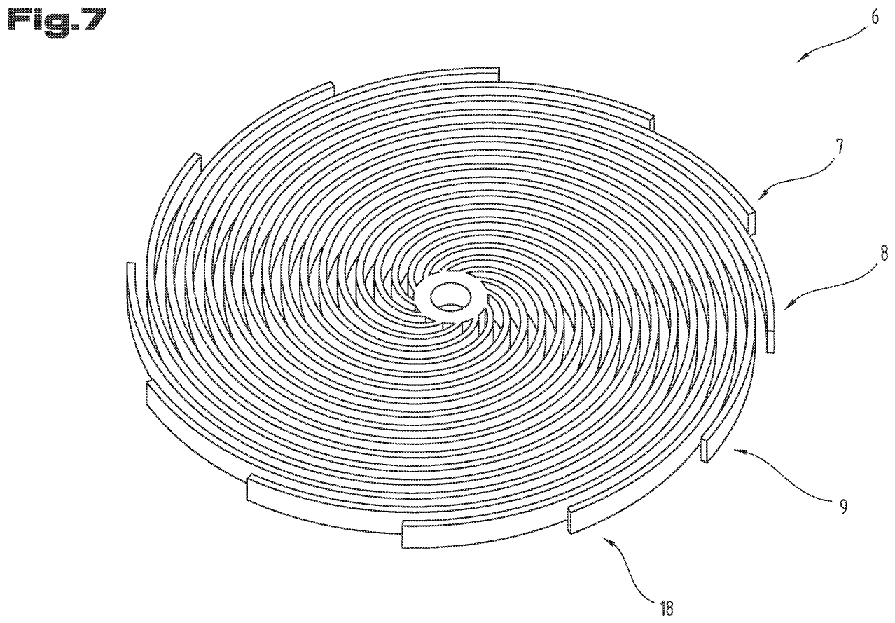

FIG. 6 an embodiment variant of a temperature control device:

FIG. 7 an embodiment variant of a temperature control device.

By way of introduction, it should be noted that in the differently described embodiments, the same parts are provided with the same reference signs or the same component designations, whereby the disclosures contained in the entire description can be transferred analogously to the same parts with the same reference signs or the same component designations. The position details selected in the description, such as top, button, side, etc., also refer to the directly described and illustrated figure and these position details are to be transferred analogously to the new position if the position is changed.

FIG. 1 shows a simplified side view of a temperature control device 1. The temperature control device 1 can be an oven or a heating device and/or a cooling device. Accordingly, the temperature control device 1 can be used to warm or heat a material or to cool a material or to maintain the material at a defined temperature level. Preferably, the temperature control device 1 is used for heating or melting a solid material (solid), in particular for growing or producing a single crystal, such as aluminum oxide (sapphire), Si, SiC, etc. Although the use of the temperature control device 1 in single crystal production is one of the preferred applications, it should be noted, however, that the invention is not limited to this field of application.

In the following, the temperature control device 1 is described as a heating device for a clearer presentation of the invention. However, these explanations can also be adopted accordingly for the “cooling device” embodiment, unless explicitly stated otherwise, such as “in the heating device embodiment”. Formulations such as “material to be heated” or “oven” are therefore also to be read as “material to be cooled” or “material to be kept at a temperature”, “cooler”, etc.

The temperature control device 1 according to FIG. 1 comprises a receptacle for the material to be heated, such as a shelf on which the material to be heated is placed. In particular, according to one embodiment of the temperature control device 1, the receptacle can be a crucible 2 or a receptacle container into which the material is filled for temperature control and in which it is melted if necessary.

The crucible 2 is preferably cylindrical with a circular base 3. However, the crucible 2 can also have a different cross-sectional shape, for example rectangular, square or generally polygonal. Furthermore, the crucible 2 can also have a shape that deviates from the cylindrical shape, for example a truncated cone shape or generally with a cross-section that widens towards an opening 4 for filling the material.

If the temperature control device 1 is used to produce a single crystal, the latter is preferably not pulled out of the crucible 2. The finished single crystal can, for example, have a diameter of between 5 cm and 50 cm and a height of between 5 cm and 80 cm. However, it should be noted that these values are for illustrative purposes and should not be understood as limiting the scope of protection.

For the sake of completeness, it should be mentioned at this point that the temperature control device 1 comprises or may comprise elements other than those mentioned in this description, such as a control and/or regulating unit, etc. However, since these may correspond to the state of the art, they will not be discussed further in this description, but reference will be made to the relevant state of the art.

The temperature control device 1 preferably has a housing 5 to form a receiving chamber (also referred to as an oven space) in which the receptacle and the material to be heated can be arranged at least during heating.

The temperature control device 1 also has at least one temperature control apparatus 6, which is arranged in particular in the receiving space of the temperature control device 1.

The temperature control apparatus 6 is arranged in particular below the receptacle for the material, for example below the bottom surface 3 of the crucible 2. Alternatively, the temperature control apparatus 6 can also be arranged in another area of the temperature control device 1, for example to the side or above the receptacle for the material to be heated. It is also possible that several temperature control apparatuses 6 are arranged in the temperature control device 1, for example below and to the side and/or above the receptacle for the material to be heated, as shown partially dashed in FIG. 1.

As can be better seen from FIG. 2, which shows an embodiment variant of a detail of the temperature control apparatus 6 belonging to the invention, the temperature control apparatus 6 has a first temperature control element 7 and a second temperature control element 8. The (preferred) embodiment variant of the temperature control apparatus 6 shown in FIG. 2 also has a third temperature control element 9. However, it should be noted that the temperature control apparatus 6 can also have only the first and second temperature control elements 7, 8, as can be seen in FIG. 3, or can have more than three temperature control elements 7, 8, 9, as can be seen in FIGS. 6 and 7.

The first and second temperature control elements 7, 8 and, in particular, the third temperature control element 9 or any other temperature control element that may be present are formed to be at least sectionally spiral-shaped. In particular, each of the temperature control elements 7, 8, 9 of the temperature control apparatus 6 is spiral-shaped. For clarification, it should be noted that spirals are structures in a plane and should not be confused with coils, such as heating coils. The temperature control elements 7, 8, 9 are not helical, i.e. they do not follow the course of helixes.

By “at least sectionally spiral-shaped”, it is meant that the temperature control elements 7, 8, 9 have start and end sections that can have a course that deviates from the spiral-shaped course.

Between the start and end sections, however, the temperature control elements 7, 8, 9 follow the spiral-shaped course.

The temperature control elements 7, 8, 9 are at least partially or at least sectionally nested within one another. Due to this nesting, in the embodiment variant of the temperature control apparatus 6 shown in FIG. 3, the first temperature control element 7 is arranged sectionally directly between the second and third temperature control elements 8, 9, the second temperature control element 8 is arranged sectionally directly between the first and third temperature control elements 7, 9 and the third temperature control element 9 is arranged sectionally directly between the first and second temperature control elements 7. Generally, due to the nesting, the temperature control elements of the temperature control apparatus 6 are arranged at least sectionally between other temperature control elements of the temperature control apparatus 6 or at least one other temperature control element of the temperature control apparatus 6.

Only the temperature control elements 7, 8, 9 of the temperature control apparatus 6 are shown in FIG. 2. However, the temperature control apparatus 6 can also have other components or parts, such as a regulating and/or control device, a housing, etc. In this regard, reference is made to the known state of the art for heating apparatus.

The temperature control apparatus 6 is preferably assigned to the bottom surface 3 or the opening 4 of the crucible 2. In particular, the version of the temperature control apparatus 6 shown in FIG. 2 is assigned to a crucible 2 with a circular bottom surface 3 or circular opening 4 or is arranged at a distance from it.

The embodiment variant of the temperature control device 1 shown in FIG. 1 has several temperature control apparatuses 6. One or more or all of these temperature control apparatuses 6 can be configured according to the invention. However, the temperature control apparatus 6 according to the invention can also be combined with temperature control apparatuses known from the prior art or can also be used alone as the only temperature control apparatus 6 of the temperature control device 1.

Several temperature control apparatuses 6 can also be combined with each other in the temperature control device 1. In this case, the combined temperature control apparatus 6 has several (at least two) groups of spirally arranged temperature control elements 7, 8 and possibly 9 that are nested within one another. These can be arranged below (below the bottom surface 3) and/or above (above the opening 4) and/or to the side of the receptacle for the material to be heated, in particular the crucible 2.

It is also possible that the temperature control apparatus 6 arranged below (below the bottom surface 3) and/or above (above the opening 4) and/or to the side of the receptacle for the material to be heated, in particular the crucible 2, also has/have at least two or more groups of temperature control elements 7, 8 and possibly 9 arranged to be spiral-shaped and nested within one another.

In the heating device embodiment, the temperature control elements 7, 8, 9 can be formed as resistance heating elements. Since resistance heating elements are known per se, reference is made to the relevant state of the art.

However, the temperature control elements 7, 8, 9 can also be formed as pipes and have a heating fluid or a cooling fluid, such as water, flowing through them.

The distance between the temperature control elements 7, 8, 9 and the material to be heated can, for example, be between 3 cm and 150 cm, in particular between 10 cm and 50 cm. However, according to one embodiment of the temperature control device 1, it is also possible for at least the temperature control elements 7, 8, 9 to rest against a surface of the receptacle, in particular the crucible 2, in particular to rest directly against it.

As explained, the first temperature control element 7, the second temperature control element 8 and the third temperature control element 9 have a spiral-shaped course, at least sectionally. The spiral section can be in the form of an Archimedean, hyperbolic or logarithmic spiral. Other spiral-shaped courses or combinations of different spiral-shaped courses are also possible.

According to preferred embodiment variants of the temperature control apparatus 6, the spirals of the first and second temperature control elements 7, 8 are formed as Fibonacci spirals and/or the spiral of the third temperature control element 9 is formed as a Fibonacci spiral. These embodiment variants are shown in FIG. 2. This is based on the so-called Fibonacci numbers, i.e. a sequence of numbers in which each element is formed from the sum of the two previous numbers (0, 1, 1, 2, 3, 5, 8, 13, 21, . . . ). The Fibonacci spiral is formed in such a way that the radii of directly consecutive circular sectors of this Fibonacci number sequence are selected. The Fibonacci spiral can be approximated as a series of quarter-circle arcs, whereby the quarter-circle arcs with a radius of 1 or the smallest number from the Fibonacci number sequence are arranged at the inner end of the Fibonacci spiral. Due to the start of the Fibonacci number sequence, a semicircle with a radius of 1 can be formed at the inner end. The temperature control elements of the temperature control apparatus 6 can be scaled according to the Fibonacci numbers. Designing the temperature control elements as Fibonacci spirals has the advantage that the individual temperature control elements can be better nested within one another.

FIG. 3 is intended to illustrate that other spiral forms for the temperature control elements 7, 8 are also possible within the scope of the invention, for example temperature control elements 7, 8 which have a sectional course in the form of a rectangular, in particular square, spiral. In general, the temperature control elements 7, 8 can have a course in the form of polygonal spirals. Such at least square spiral forms are used in particular for a receptacle for the material to be heated, in particular crucible 2, which has a corresponding polygonal bottom surface, in particular bottom surface 3. For example, a rectangular spiral-shaped course is used for a crucible 2 with a rectangular bottom surface 3 or a square spiral-shaped course for a crucible 2 with a square bottom surface 3. The shape of the temperature control apparatus 6, i.e. the temperature control elements 7, 8, 9 (viewed from above) is therefore preferably based on the shape of the receptacle for the material to be heated, in particular the shape of the bottom surface 3 of the crucible 2. In particular, the temperature control apparatus 6, i.e. the temperature control elements 7, 8, 9 (viewed from above) therefore preferably have the same shape as the receptacle for the material to be heated, in particular the shape of the bottom surface 3 of the crucible 2, although there may be differences in size.

Preferably, the temperature control apparatus 6 has a surface expansion that corresponds to at least 70%, in particular between 80% and 100%, of the surface expansion of the receptacle for the material to be heated, in particular the bottom surface 3 of the crucible 2.

This surface expansion corresponds to the surface expansion of the temperature control elements 7, 8, 9 without any first connection elements 10 for the connection of the temperature control elements 7, 8, 9 to a fluid supply system or for the electrical contacting of the temperature control elements 7, 8, 9. Each of the temperature control elements 7, 8, 9 has (in particular in the embodiment with resistance heating elements) the first connection area 10 and a second connection area 11 for electrical contacting. The first connection areas 10 are at the outer beginning and the second connection areas 11 at the inner end of the temperature control elements 7, 8, 9. The first connection areas are those areas that deviate from the spiral shape, for example the sections on the outer circumference of the temperature control apparatus 6 or the temperature control elements 7, 8, 9 that run at an angle to the further course of the temperature control elements 7, 8, 9 in FIG. 2.

The first and second connection areas 10, 11 can also be configured for the connection of a fluid, for example water.

As can be seen in FIG. 3, the first and/or second connection areas 10, 11 can be arranged side-by-side to each other. According to a preferred embodiment of the temperature control apparatus 6, however, the first connection areas 10 are arranged offset by 120° to each other, as shown in FIG. 2. Other arrangements of the first connection areas 10 with an offset to each other in the circumferential direction of the temperature control apparatus 6 or the temperature control elements 7, 8, 9 are also possible, for example in a range between 30° and 110°, although the 120° embodiment variant is the preferred one.

In particular, in the embodiment variant with the resistance heating elements, the first, second and third temperature control elements 7, 8, 9 can preferably form first and second connection areas 10, 11 for electrical contacting in the form of a three-phase connection. The three-phase connection can be in the form of a delta connection. In the preferred embodiment of the temperature control apparatus 6, however, the three-phase connection is formed as a star connection, with the second connection areas 11 of the first, second and third temperature control elements 7, 8, 9 forming the star point 12 of the star connection, as shown in FIG. 2.

In the embodiment of the temperature control elements 7, 8, 9 as fluid lines, the temperature control elements 7, 8, 9 can also have a common connection in the middle of the temperature control apparatus 6, into which the or all temperature control elements 7, 8, 9 of the temperature control apparatus 6 open. In the broadest sense, this embodiment variant of the temperature control apparatus 6 therefore also has a “star point”.

The first and/or second connection areas 10, 11 can be provided with openings, for example bores, so that the first and/or second connection areas 10, 11 can also serve as fastening points for the temperature control elements 7, 8, 9, in particular for holding screws or other fastening means.

The temperature control elements 7, 8, 9 can be formed as round or flat wires or as electrical conductors with a polygonal, for example rectangular or square, cross-section or as tubes with a round or polygonal, for example rectangular or square, cross-section. For example, the temperature control elements 7, 8, 9 can have a width 13 of between 0.1 mm and 50 mm and a height 14 of between 0.1 mm and 50 mm. They can also have a length of between 10 cm and 200 cm between the two connection areas 10, 11. For example, a round wire can have a diameter of between 5 mm and 1000 mm. Other forms of temperature control elements 7, 8, 9 can have a cross-sectional area of between 0.01 mm² and 2500 mm² or between 0.01 mm² and 0.1 m². However, this information should not be understood as limiting the scope of protection. The temperature control elements 7, 8, 9 can also be larger or smaller. The temperature control elements 7, 8, 9 can also have sections with different cross-sectional shapes along their course.

The temperature control elements 7, 8, 9 have or consist of a metallic material, preferably a metallic alloy. For example, the temperature control elements 7, 8, 9 comprise or consist of manganese, constantan, platinum, etc. Semiconductors, such as silicon carbide, molybdenum disilicide, etc., can also be used, particularly for higher temperatures. The temperature control elements 7, 8, 9 can also be made of or consist of another material, such as graphite in the version as a heating device.

According to other embodiments, it may be provided that a distance 15 between the first and the second temperature control element 7, 8 is at most 50 mm, for example between 1 mm and 10 mm, and/or that a distance 15 between the first and the third temperature control element 7, 9 and/or between the second and the third temperature control element 8, 9 is at most 50 mm, for example between 1 mm and 10 mm. The distance 15 is measured between directly adjacent sections of the temperature control elements 7, 8, 9.

FIG. 4 shows a detail of an embodiment variant of a temperature control device 1. The receptacle for the material (to be heated), in particular the crucible 2, and the temperature control apparatus 6 are shown. The temperature control device 1 also has at least one reflector element 16. In this embodiment variant, the temperature control apparatus 6 is arranged between the reflector element 16 and the receptacle for the material to be heated, in particular the crucible 2. The reflector element 16 can be made of a ceramic material or graphite, for example.

According to a further embodiment, it may be provided that the first, second and third temperature control elements 7, 8, 9 of the temperature control apparatus 6 are connected to a load sharing control 17. This makes it possible to at least reduce differences in the heating outputs of the temperature control elements 7, 8, 9 or to equalize the heating outputs of the temperature control elements 7, 8, 9.

For the sake of completeness, FIG. 5 shows an embodiment of the temperature control apparatus 6 that only has the first and second temperature control elements 7, 8, which, unlike those shown in FIG. 3, are formed here as Fibonacci spirals. Preferably, the first connection areas 10 are arranged rotated to each other by 180°.

It is also possible for the temperature control elements 7, 8, 9 to be nested several times, in particular in the form of Fibonacci spirals. To illustrate these embodiment variants, FIGS. 6 and 7 show a six fold or sixteen fold nesting in which the temperature control elements 7, 8, 9 are arranged nested with six or thirteen further temperature control elements 18 as described above, and in particular can also have a common star point 12.

In general, the multiple nested temperature control elements 7, 8, 9, 18 can also be used to implement different temperature control stages or switching stages, so that the temperature control elements 7, 8, 9, 18 can control the temperature to different degrees or thus also enable surface adaptation to different large exceptions for the material, so that, for example, only an inner ring of the temperature control apparatus 6 can be used for temperature control if required.

The exemplary embodiments show or describe possible embodiment variants of the temperature control device 1 or the temperature control apparatus 6, whereby it should be noted at this point that combinations of the individual embodiment variants are also possible.

Finally, for the sake of order, it should be noted that for a better understanding of the structure of the temperature control device 1 or the temperature control apparatus 6, these are not necessarily shown to scale.

### LIST OF REFERENCE SYMBOLS

1 Temperature control device
2 Crucible
3 Bottom area
4 Opening
5 Housing
6 Temperature control apparatus
7 Temperature control element
8 Temperature control element
9 Temperature control element
10 Connection area
11 Connection area
12 Star point
13 Width
14 Height
15 Distance
16 Reflector element
17 Load sharing control
18 Temperature control element

1. A temperature control device (6) comprising a first temperature control element (7), which has at least sectionally a spiral-shaped course, and at least one second temperature control element (8), which also has at least sectionally a spiral-shaped course, the first and second temperature control elements (7, 8) being positioned so as to be at least partially nested within one another, wherein the spiral-shaped courses of the first and second temperature control elements (7, 8) are formed as Fibonacci spirals.

2. (canceled)

3. The temperature control device (6) according to claim 1 further comprising at least one third temperature control element (9) and optionally at least one further temperature control element (18) being arranged so as to be at least partially nested with the first and second temperature control elements (7, 8).

4. The temperature control device (6) according to claim 3, wherein the spiral-shaped course of the third temperature control element (9) and optionally of the further temperature control element (18) or of the further temperature control elements (18) is or are formed as a Fibonacci spiral(s), optionally nested several times.

5. The temperature control device (6) according to claim 3 wherein the first, the second and the third temperature control element (7, 8, 9) each have a first and a second connection area (10, 11) for electrical contacting, the first connection areas being arranged offset from one another by 120°.

6. The temperature control device (6) according to claim 3, wherein all temperature control elements (7, 8, 9, 18) have a common second connection area (11).

7. The temperature control device (6) according to claim 5, wherein the first and a second connection areas (10, 11) form a three-phase connection.

8. The temperature control device (6) according to claim 7, wherein the three-phase connection is formed as a star connection, the second connection areas (11) of the first, second and third temperature control elements (7, 8, 9) forming the star point (12) of the star connection.

9. The temperature control device (6) according to claim 1, wherein the first and second temperature control elements (7, 8) are formed to be at least sectionally flat wire-shaped.

10. The temperature control device (6) according to claim 3, wherein the third temperature control element (9) and the optionally present further temperature control element (18) or the optionally present further temperature control elements (18) are formed to be at least sectionally flat wire-shaped.

11. The temperature control device (6) according to claim 1, wherein a distance (15) between the first and the second temperature control element (7, 8) is at most 50 mm.

12. The temperature control device (6) according to claim 3, wherein a distance (15) between the first and the third temperature control element (7, 9) and/or between the second and the third temperature control element (8, 9) is at most 50 mm.

13. A temperature control device (1) with a receptacle for a material to be heated and with a temperature control device (6) for heating the material, wherein the temperature control device (6) is formed according to claim 1.

14. The temperature control device (1) according to claim 13, wherein the temperature control device (6) is arranged between at least one reflector element (16) and the receptacle for the material to be heated.

15. The temperature control device (1) according to claim 13 wherein the receptacle for the material to be heated is formed as a crucible (2).

16. The temperature control device (1) according to claim 13, wherein the first, the second and the third temperature control element (7, 8, 9) of the temperature control device (6) are connected to a load sharing control (17).
